(19) United States
(12) Patent Application Publication
(10) Pub. No.: US 2011/0204514 A1
(43) Pub. Date: Aug. 25, 2011

(54) PACKAGE DEVICE AND FABRICATION METHOD THEREOF

(76) Inventor: Chung-Chi CHEN, Hsinchu (TW)

(21) Appl. No.: 12/815,087

(22) Filed: Jun. 14, 2010

(30) Foreign Application Priority Data
Feb. 23, 2010 (TW) 099108465

(51) Int. Cl. H01L 23/498; H01L 21/60

(52) U.S. Cl. 257/738; 438/107; 257/E23.069; 257/E21.509

(57) ABSTRACT

A package device and a fabrication method thereof comprises providing a plurality of package units each having a plurality of penetrated holes; stacking the plurality of package units in a manner such that the penetrated holes of the plurality of package units are aligned; filling a conductive material into the plurality of penetrated holes substantially, so as to electrically connect the plurality of package units through the conductive material; and disposing a plurality of solder balls on the bottom of the conductive material filling the plurality of penetrated holes, and connecting the plurality of solder balls with the conductive material electrically.

### BACKGROUND OF THE INVENTION

1. Field of the Invention

The present invention is related to a package device and the fabrication method thereof, and more particularly to a package device and the fabrication method thereof having a plurality of package units stacked.

2. Description of the Prior Art

The electronic products nowadays develop according to the trend toward a lighter, thinner, shorter and smaller device. However, when the functions of various electronic parts are growing with the demands of users, the number of pins of the semiconductor package device in electronic parts is also increasing. As a result, size reduction becomes a problem getting increasingly harder to solve. Therefore, vendors and R&D (research and development) personnel have been working hard to find various packaging technology to accommodate more semiconductor package devices under a constant area.

FIG. 1 is a schematic diagram illustrating a prior art stacked package units. As shown in the figure, two package units 1, 1′ are arranged to be stacked, and are electrically connected to each other through a plurality of solder balls 2. However, in the prior art technology, the solder ball 2 has a certain volume, and thus can cause the plurality of solder balls 2 to interfere with each other or to contact and short circuit. Besides, the overall height of the device would also be affected by the size of the solder ball 2. Therefore, it is highly desirable to provide a technology for stacking package units which avoids using solder balls to further reduce the overall height of the device.

### SUMMARY OF THE INVENTION

In order to solve the aforementioned problem, the present invention provides a package device and the fabrication method thereof, which effectively integrates more package units without increasing the area for stacking, and eliminates the need to use solder balls for electrical connection between the package units to reduce the overall height of the device.

In order to achieve the aforementioned objects, one objective of the present invention is to provide a package device comprising a plurality of package units, a plurality of penetrated holes, a conductive material, and a plurality of solder balls. The plurality of package units are arranged to be stacked. The plurality of penetrated holes penetrate the stacked package units. The conductive material substantially fills the penetrated holes, and the stacked package units are electrically connected with each other through the conductive material. The plurality of solder balls are disposed on the bottom of penetrated holes and are electrically connected with the conductive material.

Another objective of the present invention is to provide a fabrication method of the package device comprising providing a plurality of package units, each having a plurality of penetrated holes; stacking the plurality of package units, wherein the plurality of package units are arranged to be stacked in a manner such that the penetrated holes of the plurality of package units are aligned; filling the plurality of penetrated holes with a conductive material substantially so that the plurality of package units are electrically connected through the conductive material; and disposing a plurality of solder balls on the bottom of the conductive material substantially filling the plurality of penetrated holes, so that the solder balls are electrically connected with the conductive material.

The objective, technologies, features and advantages of the present invention will become more apparent from the following description in conjunction with the accompanying drawings, wherein certain embodiments of the present invention are set forth by way of illustration and examples.

### BRIEF DESCRIPTION OF THE DRAWINGS

FIG. 1 is schematic diagram illustrating a prior art stacked package units;

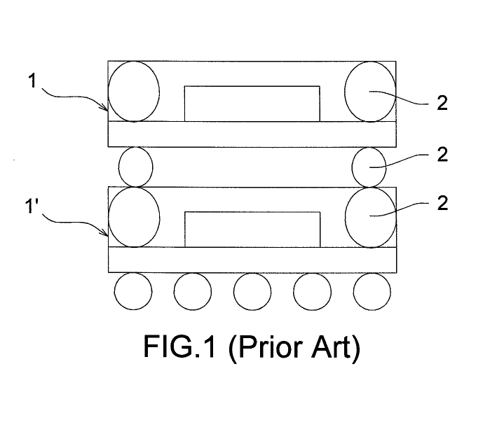

FIG. 2A to FIG. 2C are schematic diagrams illustrating the package device and the fabrication method thereof according to an embodiment of the present invention; and

FIG. 3 is a schematic structural diagram illustrating the package device according to an embodiment of the present invention.

### DESCRIPTION OF THE PREFERRED EMBODIMENT

According to the present invention, the package device and the fabrication method thereof comprises providing a plurality of package units each having a plurality of penetrated holes; stacking the plurality of package units, wherein the plurality of package units are arranged to be stacked in a manner such that their penetrated holes are aligned; filling the plurality of penetrated holes with a conductive material substantially, so that the plurality of package units are electrically connected with each other through the conductive material; and disposing a plurality of solder balls on the bottom of the plurality of penetrated holes filled with the conductive material, and connecting the plurality of solder balls electrically with the conductive material.

For clarity of description, the embodiment of the package device and the fabrication method thereof disclosed below take two package units as an example. However, as persons skilled in the art may understand, the number of package units of the package device and the fabrication method thereof according to the present invention can be adjusted according to demand.

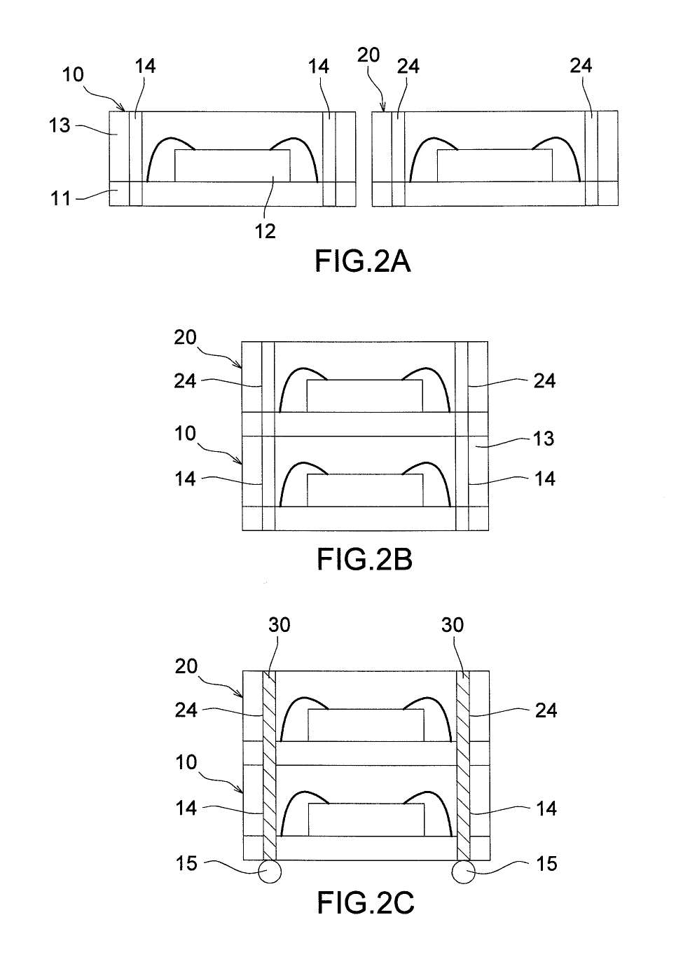

Referring to FIG. 2A to FIG. 2C, there are illustrated an embodiment of the package device and the fabrication method thereof. As shown in FIG. 2A, a first package unit 10 and a second package unit 20 are provided. The first package unit 10 and the second package unit 20 are of the same structure. The first package unit 10, taken as an example, comprises a substrate 11; at least one chip 12 disposed on the substrate 11, and electrically connected with the substrate 11 through flip chip bonding or wire bonding. The first package unit 10 can further comprise an encapsulation body 13 for encapsulating the substrate 11 and the chip 12 to a degree such that only the bottom of the substrate is exposed. In addition, the first package unit 10 and the second package unit 20 respectively have a plurality of first penetrated holes 14 and a plurality of second penetrated holes 24 respectively penetrating the first package unit 10 and the second package unit 20. For the first package unit 10, for example, the plurality of the first penetrated holes 14 penetrate the encapsulation body 13 and the substrate 11. Next, as shown in FIG. 2B, the second package unit 20 is stacked on the first package unit 10, i.e. the bottom (not indicated) of the substrate of the second package unit 20 is stacked on the encapsulation body 13 of the first package unit 10, and the plurality of second penetrated holes 24 are aligned with the plurality of first penetrated holes 14. As shown in FIG. 2C, the first penetrated holes 14 and the second penetrated holes 24 are substantially filled with a conductive material 30, so that the first package unit 10 and the second package unit 20 can connect to each other electrically through the conductive material 30, wherein the conductive material 30 can be metal such as gold, silver, nickel or copper. Next, a plurality of solder balls 15 are disposed on the bottom of the conductive material 30 substantially filling the first penetrated holes 14 and the second penetrated holes 24 so that the solder balls 15 are electrically connected with the conductive material 30.

It is noted that the method of filling the plurality of first penetrated holes 14 and the plurality of second penetrated holes 24 with the conductive material 30 may comprise heating the stacked first package unit 10 and the second package unit 20, and using a sputtering technology to sputter the conductive material into the plurality of first penetrated holes 14 and the plurality of second penetrated holes 24, wherein the heated first package unit 10 and the second package unit 20 cause the conductive material 30 to reflow in the plurality of first penetrated holes 14 and the plurality of second penetrated holes 24, thereby assuring the plurality of first penetrated holes 14 and the plurality of second penetrated holes 24 to be filled. Alternatively, the method of filling the plurality of first penetrated holes 14 and the plurality of second penetrated holes 24 with the conductive material 30 may comprise ionizing the conductive material 30 in a chamber, and then applying a negative potential to the stacked first package unit 10 and the second package unit 20 to attract the ionized conductive material 30 into the plurality of first penetrated holes 14 and the plurality of second penetrated holes 24, thereby assuring the plurality of the first penetrated holes 14 and the plurality of second penetrated holes 24 to be filled.

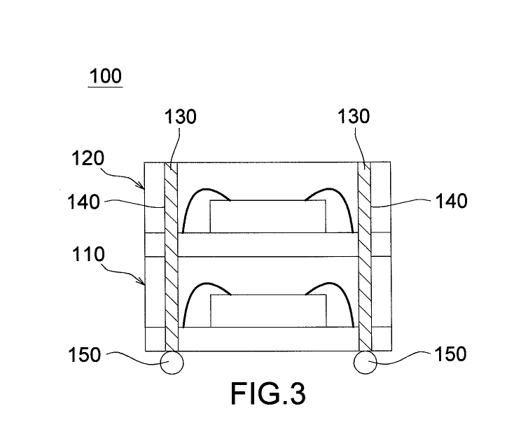

Through the aforementioned fabrication method, the present invention provides a package device as illustrated in FIG. 3. According to an embodiment illustrated in FIG. 3, the package device 100 comprises a first package unit 110, a second package unit 120, a conductive material 130, a plurality of penetrated holes 140, and a plurality of solder balls 150. As shown in the figure, the second package unit 120 is stacked on the first package unit 110. The plurality of penetrated holes 140 penetrate the first packaged unit 110 and the second package unit 120. The conductive material 130 substantially fills the plurality of penetrated holes 140 so that the first package unit 110 and the second package unit 120 are electrically connected with each other through the conductive material 130 in the plurality of penetrated holes 140. A plurality of solder balls 150 are disposed on the bottom of the conductive material 130 substantially filling the penetrated holes 140 and are connected electrically with the conductive material 130. The first package unit 110 and the second package unit 120 are of the same structure as the package unit mentioned above, and their description is therefore omitted here. Moreover, according to another embodiment, the package device 100 further comprises a plurality of adhesive layers (not indicated) disposed between the first package unit 110 and the second package unit 120, for fixing the stacked first package unit 110, and the second package unit 120.

In conclusion, the present invention provides a package device and the fabrication method thereof electrically connecting the package units with the conductive material filling the penetrated holes penetrating the stacked package units. In such way, not only does the present invention enable more package units be integrated effectively without increasing the area for stacking, but it also eliminates the need to use solder balls for electrical connection between the package units to decrease the overall height of the device.

While the invention is susceptible to various modifications and alternative forms, a specific example thereof has been shown in the drawings and is herein described in detail. It should be understood, however, that the invention is not to be limited to the particular form disclosed, but to the contrary, the invention is to cover all modifications, equivalents, and alternatives falling within the spirit and scope of the appended claims.

What is claimed is:

1. A package device comprising:
a plurality of package units, each having a plurality of penetrated holes, wherein the plurality of package units are arranged to be stacked in a manner such that the penetrated holes of the plurality of package units are aligned;
a conductive material, substantially filling the plurality of penetrated holes, wherein the plurality of package units are electrically connected with each other through the conductive material; and
a plurality of solder balls, disposed on the bottom of the conductive material substantially filling the plurality of penetrated holes, and connected electrically with the conductive material.

2. The package device according to claim 1, wherein the conductive material comprises gold, silver, nickel or copper.

3. The package device according to claim 1, wherein each of the package units comprises:
a substrate, wherein the plurality of penetrated holes penetrate the substrate; and
at least one chip disposed on the substrate, and connected electrically with the substrate.

4. The package device according to claim 3, wherein each of the package units further comprises an encapsulation body for encapsulating the substrate and the chip to a degree such that only the bottom of the substrate is exposed, wherein the plurality of penetrated holes penetrate the encapsulation body.

5. The package device according to claim 4, wherein any two of the package units are arranged to be stacked in a manner such that the bottom of the substrate of the upper package unit is stacked on the encapsulation body of the lower package unit.

6. The package device according to claim 3, wherein each of the package units further comprises a plurality of solder balls or a plurality of bond wires, connecting the chip and the substrate electrically.

7. The package device according to claim 3, further comprising a plurality of adhesive layers disposed between the plurality of package units for fixing the stacked package units.

8. A fabrication method of a package device comprising:
providing a plurality of package units, wherein each of the package unit has a plurality of penetrated holes;
stacking the plurality of package units, wherein the plurality of package units are arranged to be stacked in a manner such that the penetrated holes of the plurality of package units are aligned;
filling the plurality of penetrated holes with a conductive material substantially so that the plurality of package units are electrically connected with each other through the conductive material; and
disposing a plurality of solder balls on the bottom of the conductive material substantially filling the plurality of penetrated holes, and connecting the plurality of solder balls electrically with the conductive material.

9. The fabrication method of a package unit according to claim 8, wherein the method of filling the conductive material in the plurality of penetrated holes comprises:
heating the stacked package units; and
using a sputtering technology to sputter the conductive material into the plurality of penetrated holes, wherein the heated package units causes the conductive material to reflow in the plurality of penetrated holes thereby filling the plurality of penetrated holes.

10. The fabrication method of a package unit according to claim 8, wherein the method for providing the conductive material filling the plurality of penetrated holes comprises:
ionizing the conductive material; and
applying a negative potential to the stacked package units so as to attract the ionized conductive material into the plurality of penetrated holes to fill the plurality of penetrated holes.
